(19) United States
(12) Patent Application Publication
(10) Pub. No.: US 2026/0147017 A1
(43) Pub. Date: May 28, 2026

(54) SEMICONDUCTOR MANUFACTURING DEVICE AND METHOD OF MANUFACTURING SEMICONDUCTOR DEVICE

(71) Applicant: Mitsubishi Electric Corporation, Tokyo (JP)

(72) Inventors: Yoshiyuki UEDA, Tokyo (JP); Shunichi KAWAKAMI, Tokyo (JP)

(73) Assignee: Mitsubishi Electric Corporation, Tokyo (JP)

(21) Appl. No.: 19/299,248

(22) Filed: Aug. 13, 2025

(30) Foreign Application Priority Data
Nov. 25, 2024 (JP) 2024-204701

(51) Int. Cl. G01R 1/067; H01L 21/66; H01R 13/24

(52) U.S. Cl. CPC G01R 1/06722; H01R 13/24; H10P 74/207

(57) ABSTRACT

A semiconductor manufacturing device includes: a stage to which a semiconductor device is mounted; a support disposed above the stage and including a first substrate; and a test fixture capable of being disposed between the stage and the support. The first substrate includes, in a top surface thereof, a top surface conductive pattern electrically connected to a bottom surface portion as a portion of a bottom surface of the first substrate and includes, in a portion of the bottom surface other than the bottom surface portion of the first substrate, a bottom surface conductive pattern disposed along the top surface conductive pattern.

### BACKGROUND

### Technical Field

The present disclosure relates to a semiconductor manufacturing device and a method of manufacturing a semiconductor device.

### Description of the Background Art

Various techniques have recently been proposed for a semiconductor manufacturing device to measure electrical characteristics of a semiconductor device, such as a semiconductor chip. For example, Japanese Patent Application Laid-Open No. 2011-123015 proposes use of pogo pins for measurement of electrical characteristics of a semiconductor device.

In the conventional technique, however, outward and return conductive patterns to allow a current to flow through the semiconductor device are arranged in the same surface of the same substrate. With such a configuration, the outward and return conductive patterns arranged in the substrate increase a loop area of the current used for measurement of the electrical characteristics, leading to a problem of an increase in inductance.

### SUMMARY

The present disclosure has been conceived in view of a problem as described above, and it is an object of the present disclosure to provide a technique enabling reduction in inductance for a current during testing.

A semiconductor manufacturing device includes: a stage to which a semiconductor device is mounted; a support disposed above the stage and including a first substrate; and a test fixture capable of being disposed between the stage and the support, wherein the first substrate includes, in a top surface thereof, a top surface conductive pattern electrically connected to a bottom surface portion as a portion of a bottom surface of the first substrate, the first substrate includes, in a portion of the bottom surface other than the bottom surface portion of the first substrate, a bottom surface conductive pattern disposed along the top surface conductive pattern, the test fixture comprises: an electric needle electrically connectable to the semiconductor device; a second substrate disposed on a top side of the electric needle and including a bottom portion electrically connected to the electric needle and a top portion electrically connected to the bottom portion; and an insulating plate member covering a top portion of the electric needle on a bottom side of the second substrate and capable of electrically connecting the electric needle to the bottom portion of the second substrate, the support or the test fixture comprises a pogo pin block including a pogo pin electrically connected to any one of the bottom surface conductive pattern of the first substrate and the top portion of the second substrate and movable toward and away from the other one of the bottom surface conductive pattern of the first substrate and the top portion of the second substrate, the support or the test fixture comprises a conductive member capable of being disposed along the electric needle and capable of electrically connecting the stage to the bottom surface portion of the first substrate, and the semiconductor manufacturing device further comprises: a tester electrically connected to the bottom surface conductive pattern and the top surface conductive pattern; and a transporter to transport the test fixture toward the support to electrically connect the electric needle to the bottom surface conductive pattern via the second substrate and the pogo pin block.

Inductance can be reduced for a current during testing.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a side cross-sectional view illustrating a configuration of a semiconductor manufacturing device according to Embodiment 1;

FIG. 2 is a front cross-sectional view illustrating a configuration of the semiconductor manufacturing device according to Embodiment 1;

FIG. 3 is a side cross-sectional view illustrating a state when the semiconductor manufacturing device according to Embodiment 1 measures electrical characteristics;

FIG. 4 is a side view illustrating a configuration of a pogo pin block according to Embodiment 1;

FIG. 5 is a cross-sectional view illustrating a configuration of the pogo pin block according to Embodiment 1;

FIG. 6 is a cross-sectional view illustrating a configuration of the pogo pin block according to Embodiment 1;

FIGS. 7A and 7B are respectively a front view and a side view each illustrating a configuration of a double ended probe according to Embodiment 1;

FIG. 8 is a plan view illustrating a configuration of the semiconductor manufacturing device according to Embodiment 1;

FIG. 9 is a side cross-sectional view illustrating a configuration of a semiconductor manufacturing device according to Embodiment 2;

FIG. 10 is a front cross-sectional view illustrating a configuration of the semiconductor manufacturing device according to Embodiment 2;

FIG. 11 is a side cross-sectional view illustrating a state when the semiconductor manufacturing device according to Embodiment 2 measures electrical characteristics;

FIG. 12 is a plan view illustrating a configuration of a test fixture according to Embodiment 2;

FIG. 13 is a plan view illustrating a configuration of a test fixture according to Embodiment 3;

FIG. 14 is a cross-sectional view illustrating a configuration of the test fixture according to Embodiment 3;

FIG. 15 is a side cross-sectional view illustrating a configuration of a semiconductor manufacturing device according to Embodiment 4;

FIG. 16 is a front cross-sectional view illustrating a configuration of the semiconductor manufacturing device according to Embodiment 4;

FIG. 17 is a side cross-sectional view illustrating a state when the semiconductor manufacturing device according to Embodiment 4 measures electrical characteristics;

FIG. 18 is a plan view illustrating a configuration of a test fixture according to Embodiment 4;

FIG. 19 is a side cross-sectional view illustrating a configuration of a semiconductor manufacturing device according to Embodiment 5;

FIG. 20 is a front cross-sectional view illustrating a configuration of the semiconductor manufacturing device according to Embodiment 5;

FIG. 21 is a side cross-sectional view illustrating a state when the semiconductor manufacturing device according to Embodiment 5 measures electrical characteristics;

FIG. 22 is a plan view illustrating a configuration of the semiconductor manufacturing device according to Embodiment 5;

FIG. 23 is a side cross-sectional view illustrating a configuration of a semiconductor manufacturing device according to Embodiment 6;

FIG. 24 is a front cross-sectional view illustrating a configuration of the semiconductor manufacturing device according to Embodiment 6;

FIG. 25 is a side cross-sectional view illustrating a state when the semiconductor manufacturing device according to Embodiment 6 measures electrical characteristics;

FIG. 26 is a plan view illustrating a configuration of the semiconductor manufacturing device according to Embodiment 6; and

FIG. 27 is a flowchart showing a method of manufacturing a semiconductor device according to Embodiment 7.

### DESCRIPTION OF THE PREFERRED EMBODIMENTS

Embodiments will be described below with reference to the accompanying drawings. Features described in the embodiments below are examples, and all the features are not necessarily required. In description made below, similar components in embodiments bear the same or similar reference signs, and different components will mainly be described. In description made below, specific positions and directions, such as “top”, “bottom”, “left”, “right”, “front”, and “back”, may not necessarily match positions and directions in actual implementation.

### Embodiment 1

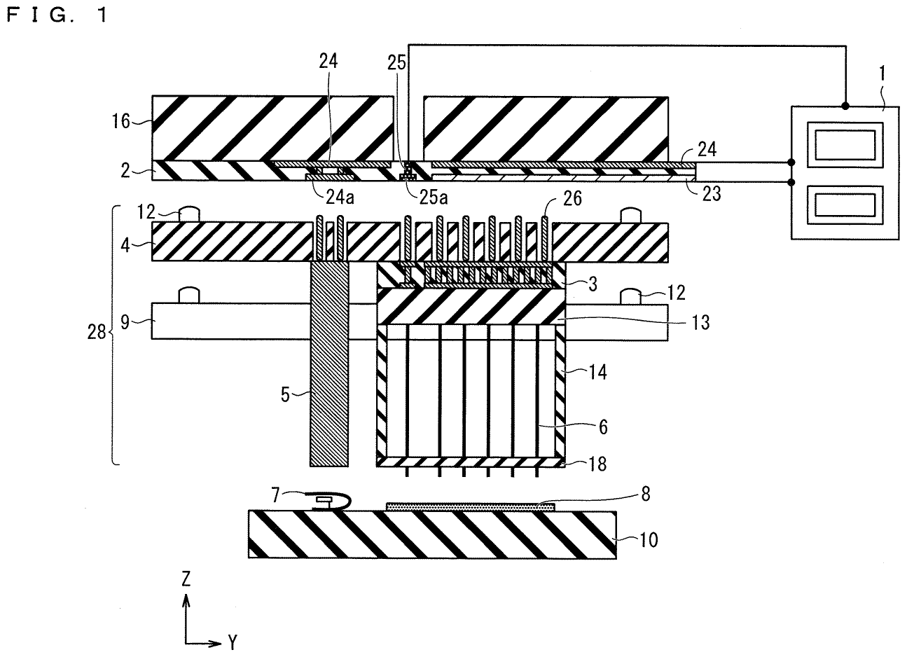

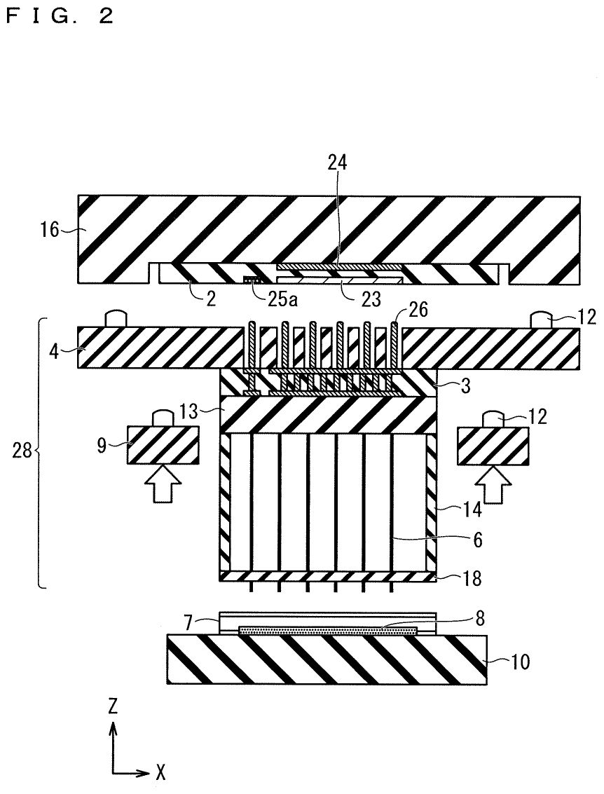

FIGS. 1 and 2 are respectively a side cross-sectional view and a front cross-sectional view each illustrating a configuration of a semiconductor manufacturing device according to Embodiment 1. The semiconductor manufacturing device according to Embodiment 1 can measure electrical characteristics of a semiconductor device 8.

The semiconductor device 8 is a semiconductor chip including a vertical power semiconductor element, for example. The semiconductor device 8 may be made of silicon (Si) as usual or may be made of a wide bandgap semiconductor, such as silicon carbide (SiC), gallium nitride (GaN), gallium oxide (Ga₂O₃), and diamond. The semiconductor device 8 made of the wide bandgap semiconductor allows for stable operation at a high temperature and a high voltage and faster switching speed of the semiconductor device 8. The semiconductor device 8 includes a metal oxide semiconductor field effect transistor (MOSFET), an insulated gate bipolar transistor (IGBT), a reverse conducting-IGBT (RC-IGBT), a Schottky barrier diode (SBD), and a PN junction diode (PND), for example.

The semiconductor manufacturing device in FIG. 1 includes a tester 1, a transport arm 9 as a transporter, a stage 10, a support 16, and a test fixture 28 as main components. The semiconductor device 8 is mounted to the stage 10. The support 16 is disposed above the stage 10, and the test fixture 28 can be disposed between the stage 10 and the support 16 by the transport arm 9, for example.

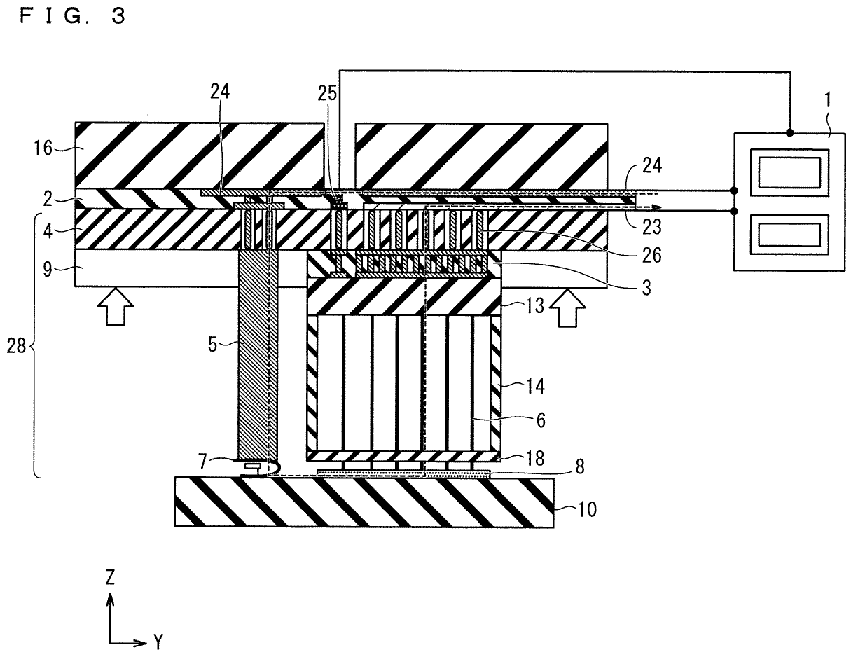

FIG. 3 is a side cross-sectional view illustrating a state when the semiconductor manufacturing device according to Embodiment 1 measures the electrical characteristics of the semiconductor device 8. Although details will be described below, the test fixture 28 is electrically connected to the support 16 through transport by the transport arm 9, and the semiconductor device 8 is electrically connected to the test fixture 28, so that the tester 1 can measure the electrical characteristics of the semiconductor device 8. Components of the semiconductor manufacturing device according to Embodiment 1 will be described in detail next.

### Support 16

The support 16 is fixed to an unillustrated body of the semiconductor manufacturing device and is generally made of resin, such as polyether ether ketone (PEEK). The support 16 includes a first substrate 2 parallel to the stage 10. The first substrate 2 has a first through hole and a second through hole each extending vertically, and a conductor is disposed in each of the first through hole and the second through hole.

As illustrated in FIG. 1, the first substrate 2 includes a top surface conductive pattern 24 in a top surface thereof. The top surface conductive pattern 24 is electrically connected to a bottom surface portion 24a as a portion of a bottom surface of the first substrate 2 by the conductor in the first through hole. A small signal pattern 25 is electrically connected to a bottom surface portion 25a as another portion of the bottom surface of the first substrate 2 by the conductor in the second through hole. The bottom surface portion 24a is a first bottom surface portion, and the bottom surface portion 25a is a second bottom surface portion. Although a left portion and a right portion of the top surface conductive pattern 24 are separated by the small signal pattern 25 in FIG. 1, the left portion and the right portion are connected to each other in a cross section other than the cross section illustrated in FIG. 1.

The first substrate 2 includes a bottom surface conductive pattern 23 in a portion of the bottom surface other than the bottom surface portions 24a and 25a. The bottom surface conductive pattern 23 is disposed along the top surface conductive pattern 24 and overlaps the top surface conductive pattern 24 in plan view. The bottom surface conductive pattern 23, the top surface conductive pattern 24, and the small signal pattern 25 described above are each electrically connected to the tester 1 by conductive wires.

While the small signal pattern 25 is electrically connected to the bottom surface portion 25a of the first substrate 2 by the through hole as with the top surface conductive pattern 24 in Embodiment 1, a configuration of the small signal pattern 25 is not limited to this configuration, and the small signal pattern 25 may be disposed in the bottom surface of the first substrate 2 as with the bottom surface conductive pattern 23. In this case, the small signal pattern 25 is included in the concept of the bottom surface conductive pattern 23.

### Test Fixture 28

The test fixture 28 includes a second substrate 3, a pogo pin block 4, a conductive member 5, electric needles 6, a first insulating plate member 13 as an insulating plate member, pillars 14, and a second insulating plate member 18.

The electric needles 6 are electrically connectable to the semiconductor device 8 as illustrated in FIG. 3. Pogo pins, wire probes, or measuring needles stretchable by buckling or elastic deformation and having conductivity are used as the electric needles 6, for example, but the electric needles 6 are not limited to them. The electric needles 6 may be subjected to surface treatment, such as gold plating.

The second substrate 3 is disposed on a top side of the electric needles 6, and a bottom portion of the second substrate 3 is electrically connected to the electric needles 6.

The first insulating plate member 13 covers a top portion of the electric needles 6 on a bottom side of the second substrate 3. The first insulating plate member 13 insulates the electric needles 6 from one another but can electrically connect the electric needles 6 to the bottom portion of the second substrate 3. For example, the first insulating plate member 13 may hold the top portion of the electric needles 6 with the top portion of the electric needles 6 being directly connected to the bottom portion of the second substrate 3 or may include an unillustrated conductor electrically connecting the top portion of the electric needles 6 to the bottom portion of the second substrate 3.

The pillars 14 supporting the second insulating plate member 18 are arranged below the first insulating plate member 13, and the electric needles 6 penetrate the second insulating plate member 18. When the first insulating plate member 13 includes pogo pins similar to pogo pins of the pogo pin block 4, which will be described below, the test fixture 28 may not include the pillars 14 and the second insulating plate member 18.

The second substrate 3 includes the bottom portion electrically connected to the electric needles 6 and a top portion electrically connected to the bottom portion. In Embodiment 1, the second substrate 3 includes a bottom conductive pattern as the bottom portion of the second substrate 3, a top conductive pattern as the top portion of the second substrate 3, and conductors arranged in through holes vertically extending through the second substrate 3. The conductors electrically connect the bottom conductive pattern to the top conductive pattern. As described above, the bottom conductive pattern as the bottom portion of the second substrate 3 is electrically connected to the electric needles 6, so that the top conductive pattern of the second substrate 3 is electrically connected to the electric needles 6 via the bottom conductive pattern. In Embodiment 1, the through holes of the second substrate 3 are located to face the bottom surface conductive pattern 23 and the bottom surface portion 25a.

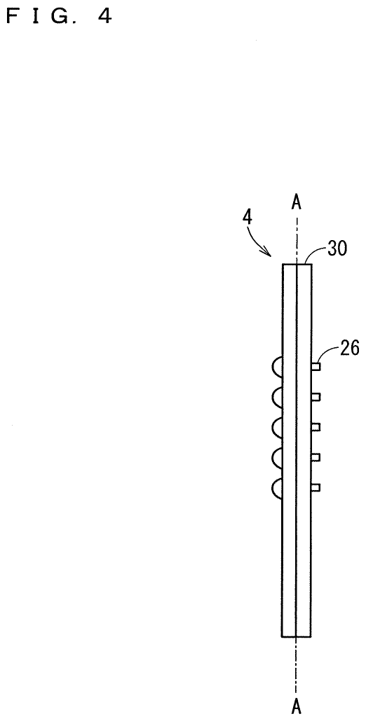

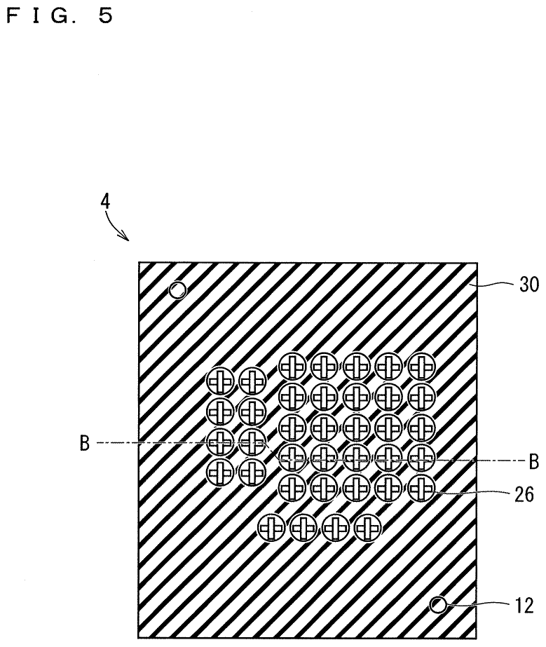

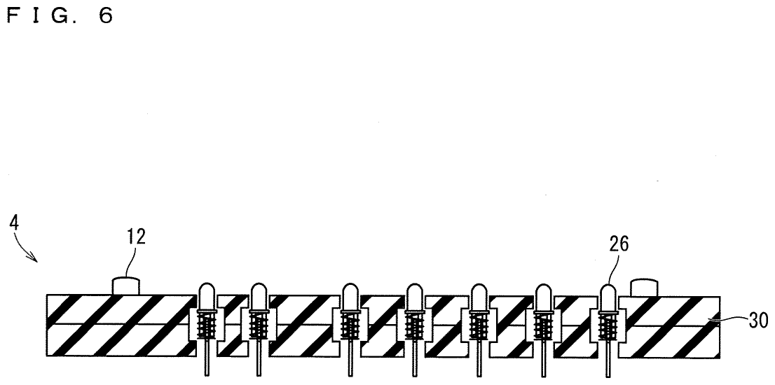

The pogo pin block 4 includes double ended probes 26 as the pogo pins, and some of the double ended probes 26 are electrically connected to the top conductive pattern of the second substrate 3 and are movable toward and away from the bottom surface conductive pattern 23 of the first substrate 2. FIG. 4 is a side view illustrating a configuration of the pogo pin block 4, FIG. 5 is a cross-sectional view taken along the line A-A of FIG. 4, and FIG. 6 is a cross-sectional view taken along the line B-B of FIG. 5.

As illustrated in FIGS. 4 to 6, the pogo pin block 4 includes the double ended probes 26 as the pogo pins and a plate-like body 30. The body 30 according to Embodiment 1 includes two plate members as illustrated in FIGS. 4 and 6. The body 30 of the pogo pin block 4 may be made of resin, such as PEEK, or may be made of heat resistant engineering plastics, for example, when testing is conducted at a high temperature of 200° C., for example.

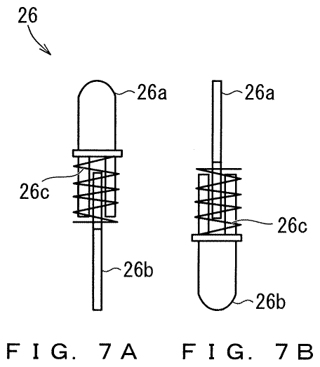

FIGS. 7A and 7B are respectively a front view and a side view each illustrating a configuration of a double ended probe 26. The double ended probe 26 includes plate members 26a and 26b and a spring 26c. As illustrated in FIG. 7A, the plate member 26a includes a first end having a radius on a top side and a second end having a recess on a bottom side, and, as illustrated in FIG. 7B, the plate member 26b includes a first end having a radius on a bottom side and a second end having a recess on a top side. The second end of the plate member 26a and the second end of the plate member 26b intersect with each other so that the second end of any one of the plate members 26a and 26b is located in the recess of the other one of the plate members 26a and 26b. In this state, the second ends of the plate members 26a and 26b are collectively wound with the spring 26c.

As illustrated in FIGS. 5 and 6, the double ended probes 26 are arranged in holes of the body 30 of the pogo pin block 4 with a loose fit. Since the plate members 26a and 26b intersect with each other, the double ended probes 26 each generally have a cross shape in FIG. 5. Opposite ends of each of the double ended probes 26 having such a configuration are elastically stretchable relative to loads and, without any loads, protrude on each side of the body 30 of the pogo pin block 4 as illustrated in FIGS. 4 and 6. In the example of FIGS. 1 to 3, bottom ends of the double ended probes 26 receive a load from the second substrate 3, so that only top ends of the double ended probes 26 protrude from the body 30 of the pogo pin block 4.

As described above, some of the double ended probes 26 are electrically connected to the top conductive pattern of the second substrate 3, and the top conductive pattern of the second substrate 3 is electrically connected to the electric needles 6. Some of the double ended probes 26 are thus electrically connected to the electric needles 6.

While the opposite ends of each of the double ended probes 26 are elastically stretchable relative to the loads in description made above, a configuration of each of the double ended probes 26 is not limited to this configuration. For example, only one end (a top end in FIGS. 1 to 3) of each of the double ended probes 26 may be elastically stretchable relative to a load. While the first end of each of the plate members 26a and 26b has the radius in FIGS. 7A and 7B, the shape of the first end is not limited to this shape, and the first end may have a V shape, or one or more of the first ends may each have the radius and the remaining one or more of the first ends may each have the V shape.

The conductive member 5 in FIG. 1 extends vertically and can be disposed along the electric needles 6. In Embodiment 1, the conductive member 5 is connected to double ended probes 26 not electrically connected to the top conductive pattern of the second substrate 3 and is supported by the double ended probes 26. As will be described below, the conductive member 5 can electrically connect a conductive elastic member 7, which will be described below, of the stage 10 to the bottom surface portion 24a of the first substrate 2 via the double ended probes 26.

A leaf spring, a pogo pin, or a wire probe stretchable by buckling or elastic deformation and having conductivity is used as the conductive member 5, for example, but the conductive member 5 is not limited to it. The conductive member 5 may be made of copper and may be subjected to surface treatment, such as gold plating.

While a configuration of the test fixture 28 has been described above, the configuration is not limited to the above-mentioned configuration. For example, depending on various positions of electrode pads (not illustrated) arranged on top sides of various semiconductor devices 8, positions of the electric needles 6 may be changeable, and the second substrate 3 may be replaceable so that the conductive patterns of the second substrate 3 can be changed. According to such a configuration, electrical characteristics of various semiconductor devices 8 differing in positions and shapes of the electrode pads can be measured without changing an arrangement pattern of the double ended probes 26. As a result, reduction in cost of the test fixture 28 to measure the electrical characteristics of various semiconductor devices 8 can be expected.

### Transport Arm 9

Although not illustrated, the semiconductor manufacturing device according to Embodiment 1 includes a plurality of test fixtures 28, and the transport arm 9 supports one of the plurality of test fixtures 28 that is suitable for measurement of electrical characteristics of the semiconductor device 8. In this case, pins 12 of the transport arm 9 position the one test fixture 28 relative to the transport arm 9.

After supporting the one test fixture 28, the transport arm 9 is moved horizontally (e.g., in a Y direction) to dispose the one test fixture 28 between the stage 10 and the support 16. Although the test fixture 28 and the transport arm 9 are illustrated to be spaced apart from each other for the sake of convenience in FIGS. 1 and 2, the test fixture 28 is actually supported by the transport arm 9.

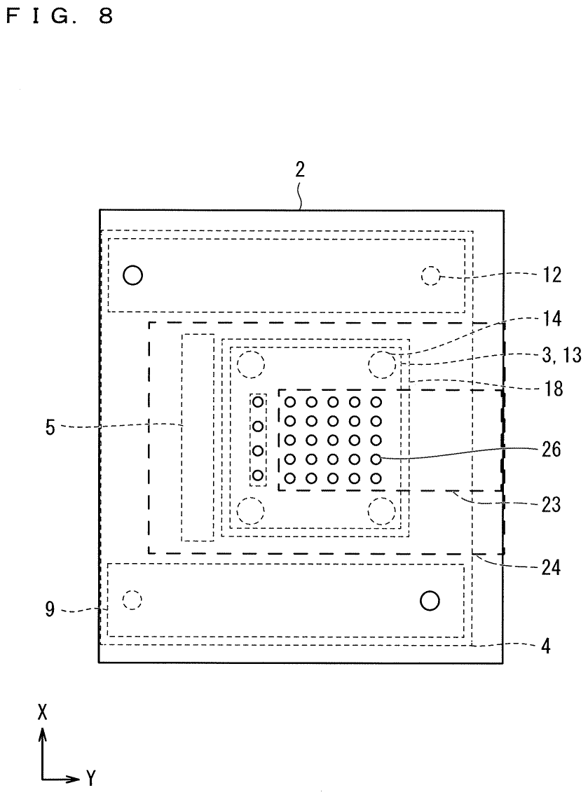

FIG. 8 is a plan view illustrating a positional relationship among the first substrate 2, the transport arm 9, and the test fixture 28 when the test fixture 28 is disposed between the stage 10 and the support 16 in Embodiment 1. In FIG. 8, the bottom surface conductive pattern 23 overlaps the top surface conductive pattern 24. In the example of FIG. 8, the transport arm 9 supports opposite ends in an X direction of the test fixture 28.

After the test fixture 28 is disposed between the stage 10 and the support 16, the transport arm 9 is moved upward (in a Z direction in FIG. 1) to transport the test fixture 28 toward the support 16. Pins 12 on the surface of the pogo pin block 4 fit into holes of the support 16, so that the double ended probes 26, the bottom surface conductive pattern 23 of the first substrate 2, and the bottom surface portions 24a and 25a are aligned.

The test fixture 28 is transported toward the support 16 to electrically connect the double ended probes 26 electrically connected to the electric needles 6 to the bottom surface conductive pattern 23 of the first substrate 2. The electric needles 6 are thereby electrically connected to the bottom surface conductive pattern 23 via the second substrate 3 and the pogo pin block 4. In the example of FIG. 3, due to the above-mentioned transport, the first substrate 2 and the pogo pin block 4 are brought into surface contact with each other, and protruding top ends of the double ended probes 26 are pushed into the surface of the body 30 of the pogo pin block 4. The pushed top ends of the double ended probes 26 press the bottom surface conductive pattern 23 by elastic recovery force, so that contact resistance between the top ends of the double ended probes 26 and the bottom surface conductive pattern 23 can be reduced, and good connection between the double ended probes 26 and the bottom surface conductive pattern 23 can be obtained.

The test fixture 28 is transported toward the support 16 to electrically connect the double ended probes 26 electrically connected to the conductive member 5 to the bottom surface portion 24a of the first substrate 2. The conductive member 5 is thereby electrically connected to the top surface conductive pattern 24 via the pogo pin block 4 and the bottom surface portion 24a. Good connection between the double ended probes 26 and the bottom surface portion 24a can be obtained by elastic recovery force of the double ended probes 26.

The test fixture 28 is transported toward the support 16 to electrically connect other double ended probes 26 electrically connected to the electric needles 6 to the bottom surface portion 25a of the first substrate 2. The electric needles 6 are thereby electrically connected to the small signal pattern 25 via the second substrate 3, the pogo pin block 4, and the bottom surface portion 25a. Good connection between the double ended probes 26 and the bottom surface portion 25a can be obtained by elastic recovery force of the double ended probes 26.

On the other hand, some of the double ended probes 26 are electrically connected to the top conductive pattern of the second substrate 3 regardless of whether the test fixture 28 is transported toward the support 16. Furthermore, the conductive member 5 is disposed along the electric needles 6 regardless of whether the test fixture 28 is transported toward the support 16.

### Stage 10

The stage 10 includes the conductive elastic member 7 disposed in a region other than a region to which the semiconductor device 8 is mounted. The conductive elastic member 7 is electrically connected, via the body of the stage 10, to an electrode (not illustrated) on a bottom side of the semiconductor device 8 mounted to the stage 10.

The semiconductor manufacturing device according to Embodiment 1 recognizes electrode pads on a top side of the semiconductor device 8, the pins 12, and the unillustrated holes of the support 16 using an unillustrated image recognition device and corrects misalignment between the electrode pads and the electric needles 6. The stage 10 is then moved toward the test fixture 28, so that the electric needles 6 are electrically connected to the electrode pads on the semiconductor device 8, and the conductive member 5 is electrically connected to the conductive elastic member 7 of the stage 10 as illustrated in FIG. 3. In this case, the conductive elastic member 7 is pushed by the conductive member 5 and is elastically deformed.

### Tester 1

The tester 1 is electrically connected to the bottom surface conductive pattern 23 and the top surface conductive pattern 24. The tester 1 in FIG. 3 is electrically connected to the electrode on the bottom side of the semiconductor device 8 via the top surface conductive pattern 24 and the conductive member 5 and is electrically connected to the electrode pads on the top side of the semiconductor device 8 via the bottom surface conductive pattern 23, the electric needles 6, and the like as indicated by a dotted arrow. For example, the electrode pads on the top side of the semiconductor device 8 correspond to an emitter pad and a small signal pad, and the electrode on the bottom side of the semiconductor device 8 corresponds to a collector. Such electrical connection allows the tester 1 to measure the electrical characteristics of the semiconductor device 8.

### Summary of Embodiment 1

According to the semiconductor manufacturing device according to Embodiment 1 as described above, the top surface conductive pattern 24 to be an outward conductive pattern and the bottom surface conductive pattern 23 to be a return conductive pattern for a current during testing for measurement of the electrical characteristics of the semiconductor device 8 are arranged respectively in the top surface and in the bottom surface of the first substrate 2 along each other. According to such a configuration, a loop area of the current can be reduced. Furthermore, the pogo pin block 4, the second substrate 3, the first insulating plate member 13, and the electric needles 6 are vertically arranged in this order, so that a path for the current can be shortened. Furthermore, the conductive member 5 is disposed along the stacked structure, so that the loop area of the current can be reduced. Inductance can thereby be reduced for the current during testing, so that a surge voltage during testing can be suppressed.

### Embodiment 2

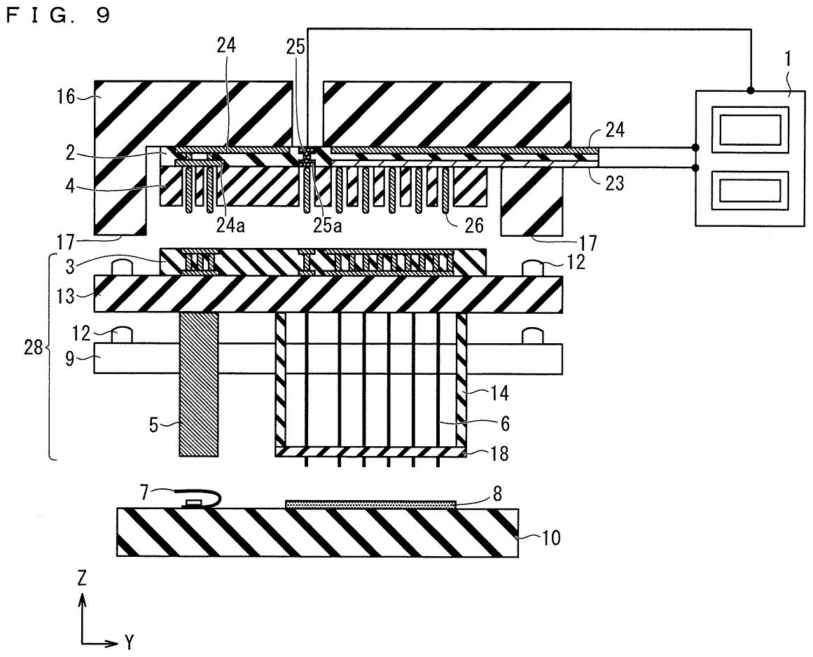

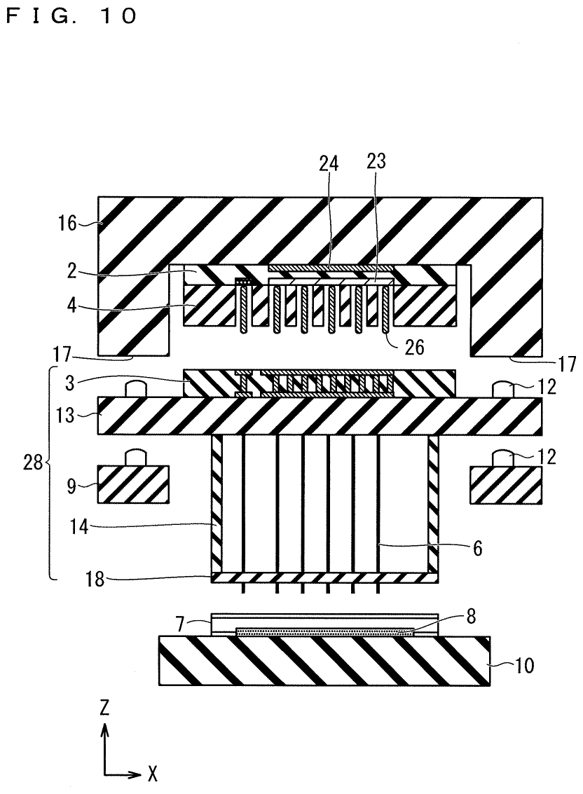

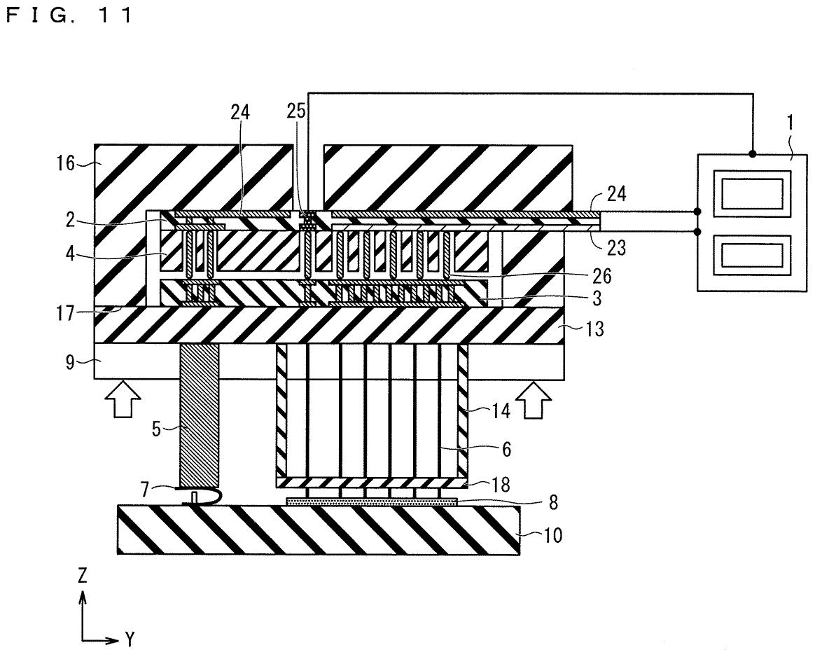

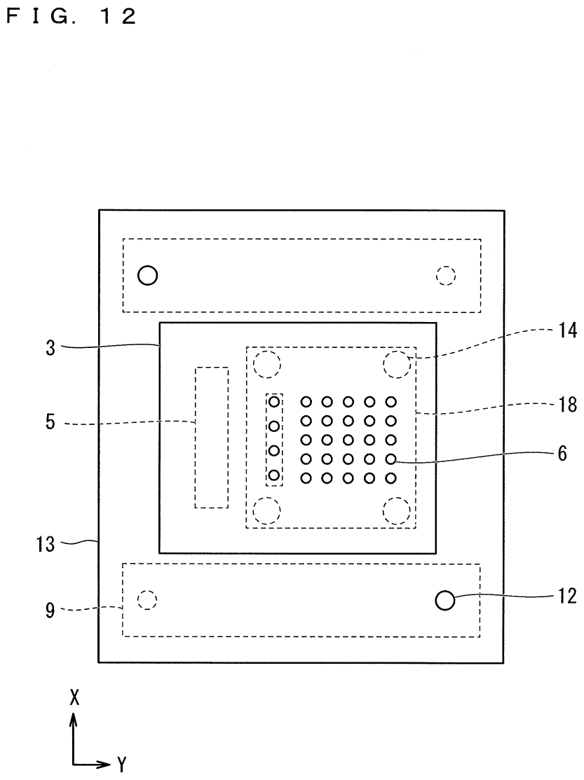

FIGS. 9 and 10 are respectively a side cross-sectional view and a front cross-sectional view each illustrating a configuration of a semiconductor manufacturing device according to Embodiment 2, and FIG. 11 is a side cross-sectional view illustrating a state when the semiconductor manufacturing device according to Embodiment 2 measures the electrical characteristics of the semiconductor device 8. FIG. 12 is a plan view illustrating a configuration of a test fixture 28 according to Embodiment 2.

While the test fixture 28 includes the pogo pin block 4 in Embodiment 1, the support 16 includes the pogo pin block 4 in Embodiment 2. In Embodiment 2, some of the double ended probes 26 are electrically connected to the bottom surface conductive pattern 23 of the first substrate 2 and are movable toward and away from the top conductive pattern of the second substrate 3. That is to say, the double ended probes 26 of the pogo pin block 4 are electrically connected to the bottom surface conductive pattern 23 of the first substrate 2 regardless of whether the test fixture 28 is transported toward the support 16. On the other hand, the test fixture 28 is transported toward the support 16 to electrically connect the double ended probes 26 of the pogo pin block 4 to the top conductive pattern of the second substrate 3.

Similarly, the other double ended probes 26 are electrically connected to the bottom surface portions 24a and 25a of the first substrate 2 and are movable toward and away from the top conductive pattern of the second substrate 3. The first insulating plate member 13 can electrically connect the conductive member 5 to the bottom conductive pattern of the second substrate 3. The test fixture 28 is thus transported toward the support 16 to electrically connect the conductive member 5 to the bottom surface portion 24a via the double ended probes 26.

According to a configuration in which the pogo pin block 4 is fixed to the support 16 as described above, the pogo pin block 4 can be omitted from the test fixture 28, so that cost of the test fixture 28 can be reduced.

In Embodiment 2, the support 16 includes an insulating restrictor 17 protruding downward. When the test fixture 28 is connected to the support 16 through transport by the transport arm 9, a portion (i.e., the body 30) of the pogo pin block 4 other than the double ended probes 26 is not in contact with the second substrate 3, but the restrictor 17 is in contact with the first insulating plate member 13. As described above, the restrictor 17 prevents contact between the body 30 of the pogo pin block 4 and the second substrate 3 and forms a gap of several tens to several hundreds of micrometers between them when the electric needles 6 are electrically connected to the bottom surface conductive pattern 23.

This gap can suppress the influence of any steps in a top surface of the second substrate 3, while electrical connection between the double ended probes 26 and the top conductive pattern of the second substrate 3 can be secured as leading ends of the double ended probes 26 are elastically stretchable. Even if the pogo pin block 4 and the second substrate 3 are slightly not parallel to each other, electrical connection between the double ended probes 26 and the top conductive pattern of the second substrate 3 can be secured. The restrictor 17 is expected to make the test fixture 28 parallel to the support 16, and, as a result, is expected to prevent disconnection of the electric needles 6 from the electrode pads on the semiconductor device 8 due to inclination of a bottom portion of the electric needles 6.

### Embodiment 3

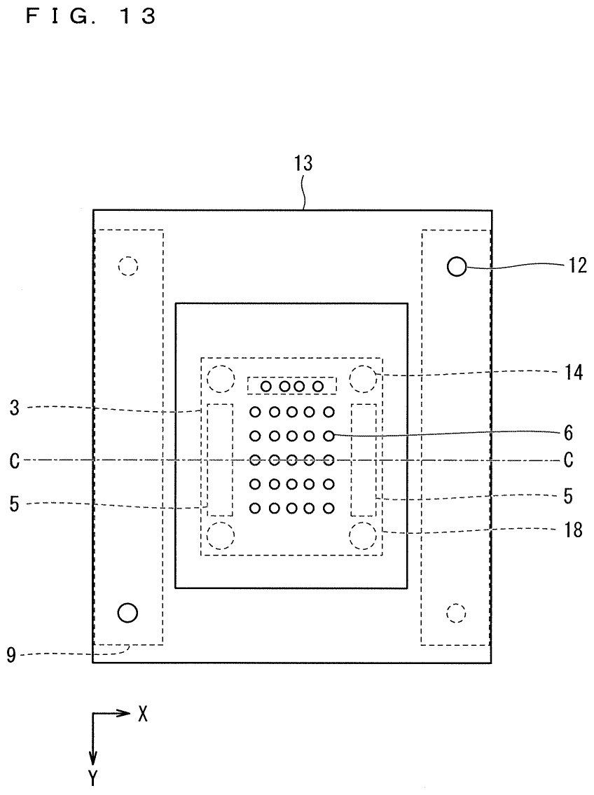

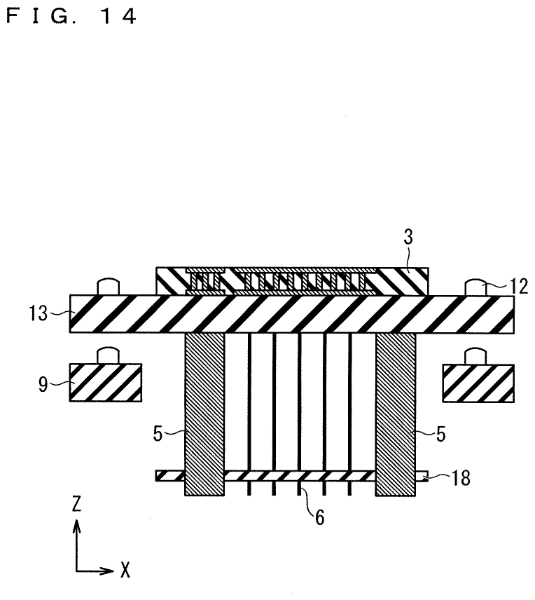

FIG. 13 is a plan view illustrating a configuration of a test fixture 28 according to Embodiment 3, and FIG. 14 is a front cross-sectional view illustrating the configuration and is a cross-sectional view taken along the line C-C of FIG. 13. In Embodiment 3, the test fixture 28 includes a plurality of (two in the example of FIGS. 13 and 14) conductive members 5. The conductive members 5 are each arranged between the pillars 14.

When an electrode pad on the top side of the semiconductor device 8 corresponds to the emitter pad, and the electrode on the bottom side of the semiconductor device 8 corresponds to the collector, the conductive members 5 are preferably brought closer to the electric needles 6 to a distance not to cause discharge due to a potential difference between the emitter and the collector. The conductive members 5 may include a material having higher insulation than air, such as polyimide tape, to enhance discharge resistance between the conductive members 5 and the electric needles 6.

A collector current generally flows through the conductive members 5 in a direction opposite a direction in which an emitter current flows through the electric needles 6, so that an effect of cancelling out their magnetic fields can be obtained. This effect can be obtained to some extent in Embodiments 1 and 2 but can be enhanced in a configuration in which the test fixture 28 includes the plurality of conductive members 5 as in Embodiment 3. Inductance can thereby be reduced for the current during testing, so that the surge voltage during testing can be suppressed.

### Embodiment 4

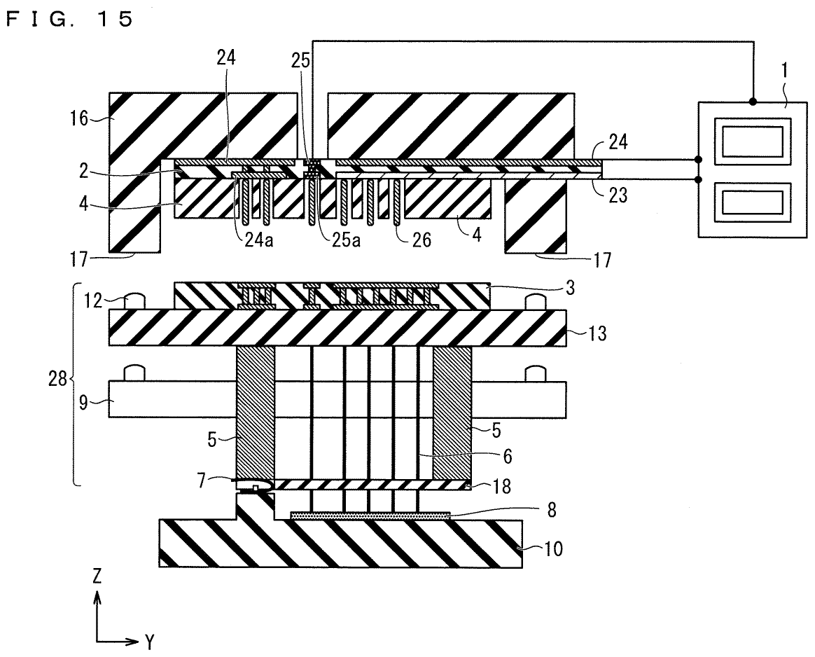

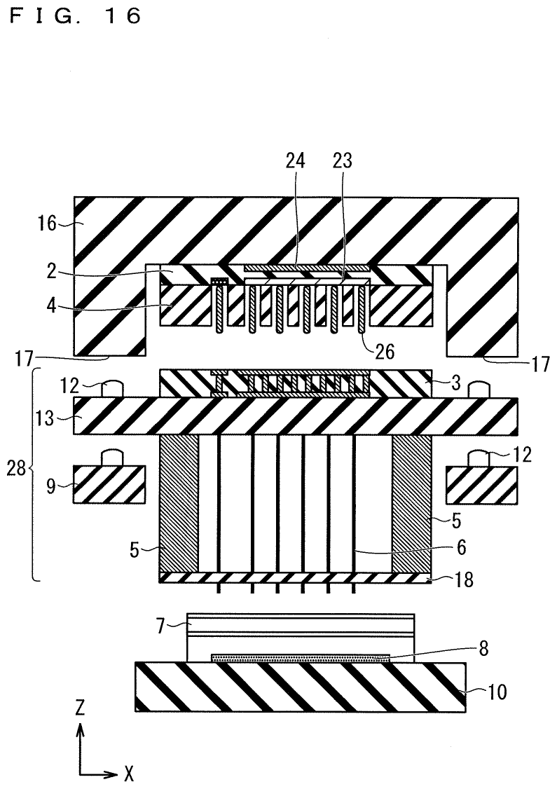

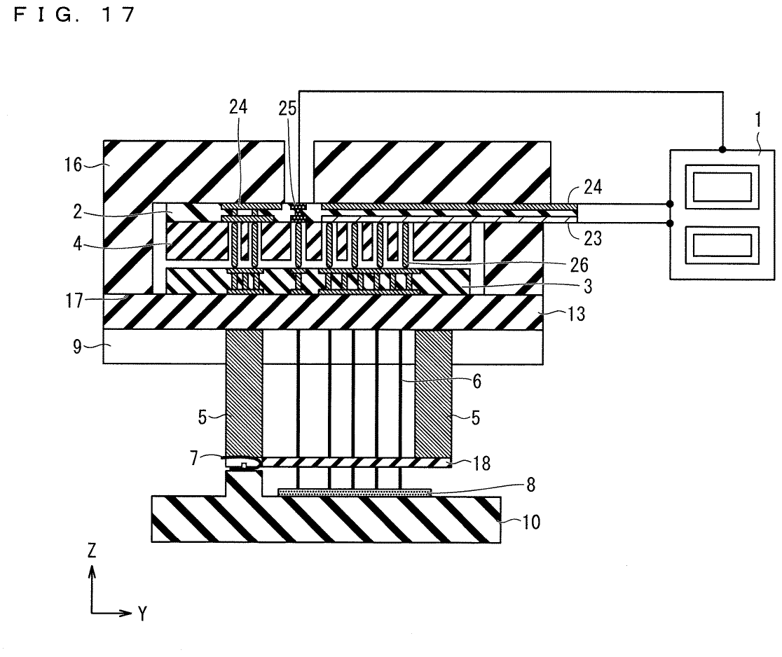

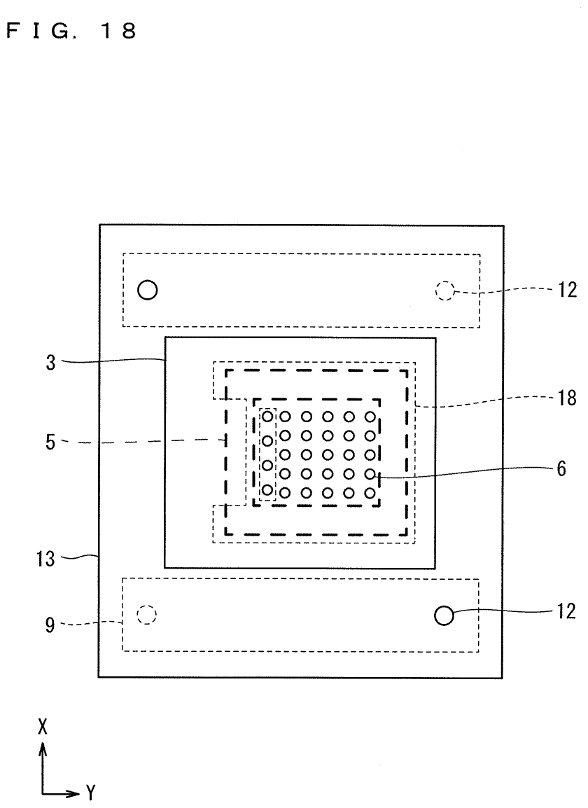

FIGS. 15 and 16 are respectively a side cross-sectional view and a front cross-sectional view each illustrating a configuration of a semiconductor manufacturing device according to Embodiment 4, and FIG. 17 is a side cross-sectional view illustrating a state when the semiconductor manufacturing device according to Embodiment 4 measures the electrical characteristics of the semiconductor device 8. FIG. 18 is a plan view illustrating a configuration of a test fixture 28 according to Embodiment 4.

In Embodiment 4, one or more conductive members 5 surround the plurality of electric needles 6 electrically connected to the semiconductor device 8 in plan view as illustrated in FIG. 18 and are used in place of the pillars 14. A portion (left portion in FIG. 18) of the second insulating plate member 18 is missing, and a conductive member 5 can be in contact with the conductive elastic member 7 in the missing portion of the second insulating plate member 18 as illustrated in FIG. 17.

According to the configuration in which the one or more conductive members 5 surround the plurality of electric needles 6 as described above, the collector current flows through the conductive members 5 in the direction opposite the direction in which the emitter current flows through the electric needles 6, so that the effect of cancelling out their magnetic fields can be enhanced. Inductance can thereby be reduced for the current during testing, so that the surge voltage during testing can be suppressed.

### Embodiment 5

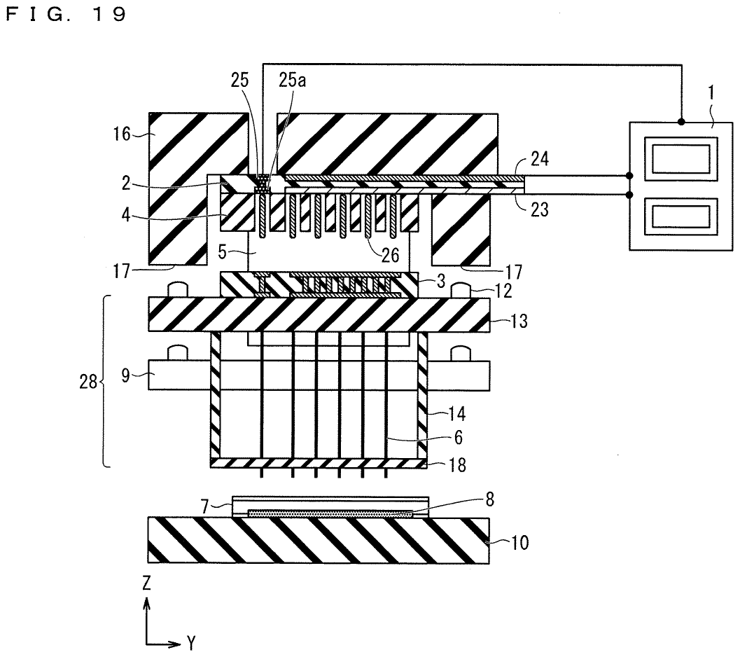

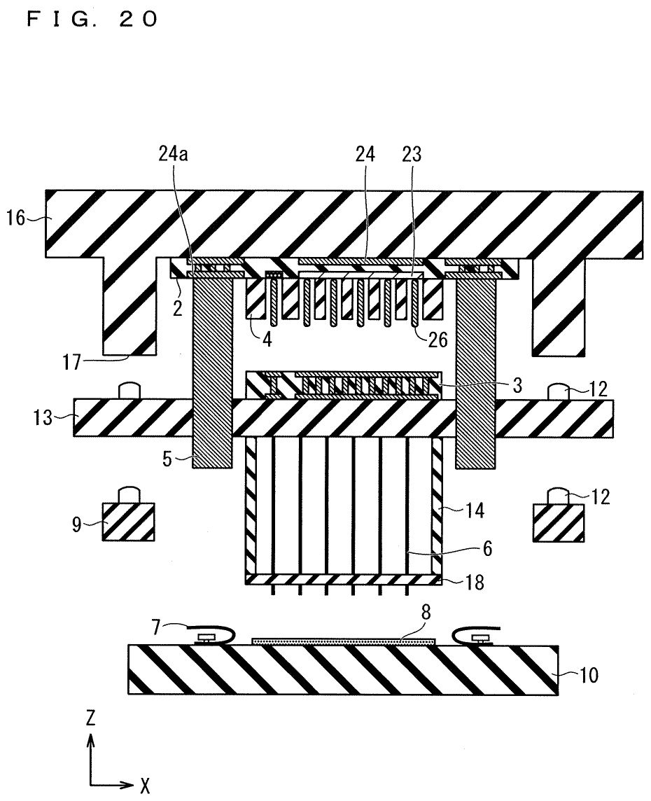

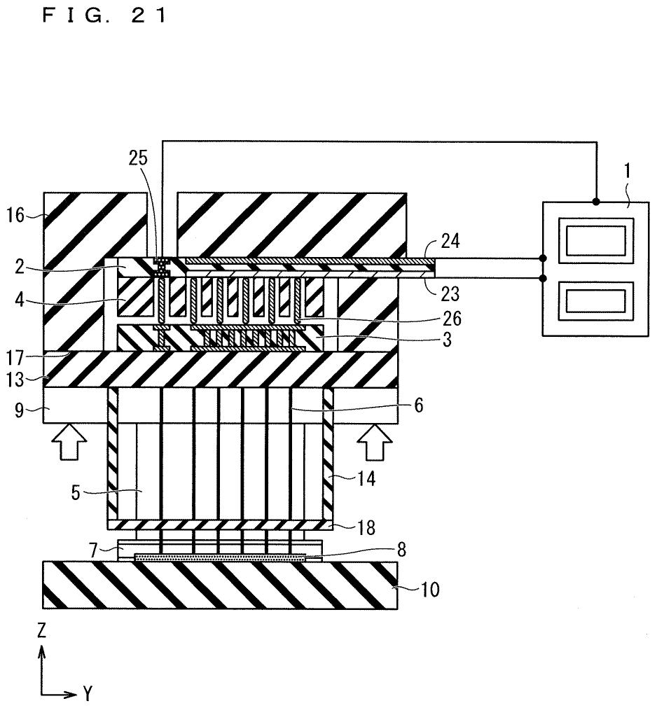

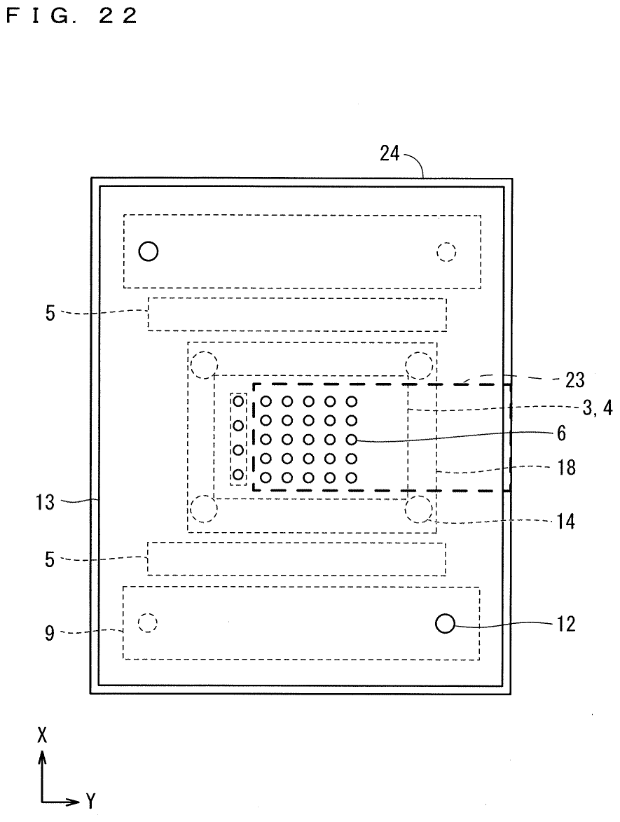

FIGS. 19 and 20 are respectively a side cross-sectional view and a front cross-sectional view each illustrating a configuration of a semiconductor manufacturing device according to Embodiment 5, and FIG. 21 is a side cross-sectional view illustrating a state when the semiconductor manufacturing device according to Embodiment 5 measures the electrical characteristics of the semiconductor device 8. FIG. 22 is a plan view illustrating a positional relationship among the first substrate 2, the transport arm 9, and the test fixture 28 when the test fixture 28 is disposed between the stage 10 and the support 16 in Embodiment 5.

While the test fixture 28 includes the conductive member 5 in each of the semiconductor manufacturing devices described so far, the support 16 includes the conductive members 5 in Embodiment 5 as illustrated in FIG. 20. That is to say, the conductive members 5 are electrically connected to the bottom surface portion 24a of the first substrate 2 regardless of whether the test fixture 28 is transported toward the support 16. On the other hand, the test fixture 28 is transported toward the support 16 to dispose the conductive members 5 along the electric needles 6. The first insulating plate member 13 has through holes into which the conductive members 5 are inserted.

According to a configuration in which the conductive members 5 are fixed to the support 16 as described above, the conductive members 5 can be omitted from the test fixture 28, so that the cost of the test fixture 28 can be reduced.

### Embodiment 6

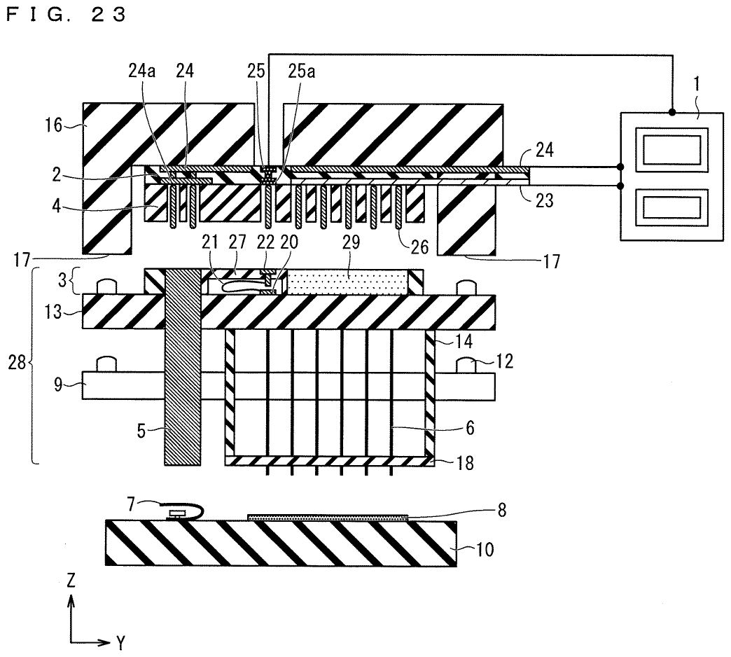

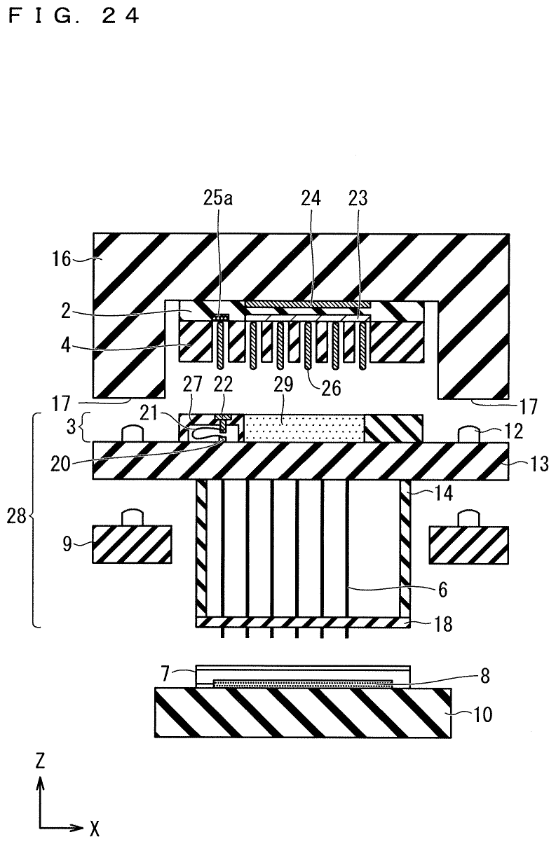

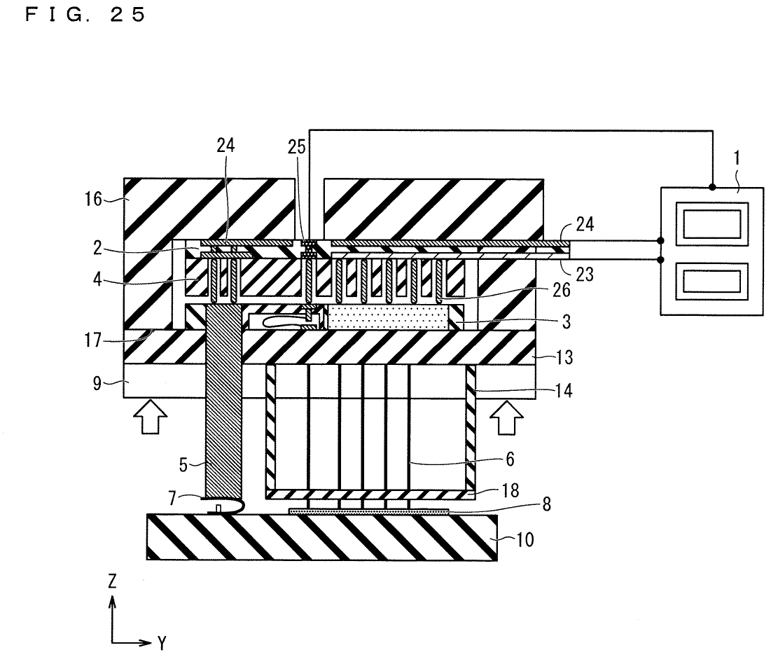

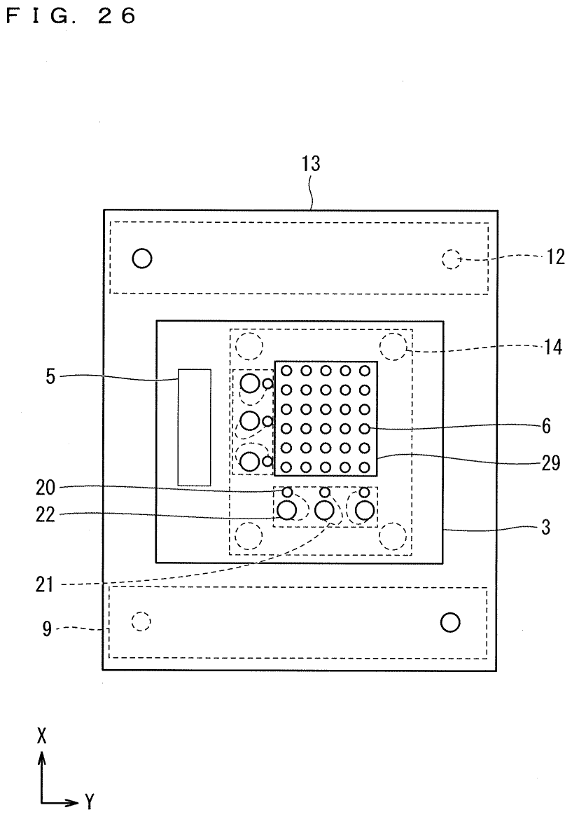

FIGS. 23 and 24 are respectively a side cross-sectional view and a front cross-sectional view each illustrating a configuration of a semiconductor manufacturing device according to Embodiment 6, and FIG. 25 is a cross-sectional view illustrating a state when the semiconductor manufacturing device according to Embodiment 6 measures the electrical characteristics of the semiconductor device 8. FIG. 26 is a plan view illustrating a positional relationship among the first substrate 2, the transport arm 9, and the test fixture 28 when the test fixture 28 is disposed between the stage 10 and the support 16 in Embodiment 6.

In each of the semiconductor manufacturing devices described so far, the second substrate 3 includes the bottom conductive pattern and the top conductive pattern electrically connected to each other by the conductors in the through holes. In contrast, in Embodiment 6, the second substrate 3 includes, in place of them, a conductive wire 21, a terminal 22, a terminal block 27, and a conductor 29, and the first insulating plate member 13 includes a protrusion 20.

The protrusion 20 of the first insulating plate member 13 protrudes from a top surface of the first insulating plate member 13 and is electrically connected to an electric needle 6. The terminal block 27 of the second substrate 3 is the top surface of the second substrate 3. The terminal 22 is disposed in the terminal block 27 and is electrically connected to the protrusion 20 by the conductive wire 21.

A plurality of conductive wires 21 may electrically be connected to a single protrusion 20 by increasing the size of the protrusion 20. The length of the conductive wire 21 is set in view of wiring work. The conductive wire 21 is housed in a cavity of the second substrate 3 formed by countersinking. The terminal block 27 is disposed to cover the cavity, is then positioned with unillustrated pins, and is fixed to the body of the second substrate 3 with screws and the like.

According to a configuration as described above, the terminal 22 of the second substrate 3 is electrically connected to the electric needle 6 via the conductive wire 21 and the protrusion 20. The conductor 29 can electrically be connected to the electric needles 6. The test fixture 28 is transported toward the support 16 to electrically connect the terminal 22 of the second substrate 3 to the small signal pattern 25 via the bottom surface portion 25a and to electrically connect the conductor 29 to the bottom surface conductive pattern 23. That is to say, the second substrate 3 includes the conductor 29 electrically connectable to the bottom surface conductive pattern 23. According to such a configuration, the electric needles 6 can electrically be connected to the small signal pattern 25 or can electrically be connected to the bottom surface conductive pattern 23 as with each of the semiconductor manufacturing devices described so far.

Depending on various positions of electrode pads (not illustrated) arranged on top sides of various semiconductor devices 8, positions of the electric needles 6 and the protrusion 20 may be changeable, and a connection pattern of the conductive wire 21 connecting the protrusion 20 and the terminal 22 may be changeable. According to such a configuration, electrical characteristics of various semiconductor devices 8 differing in positions and shapes of the electrode pads can be measured without changing the arrangement pattern of the double ended probes 26 and without replacing the second substrate 3. As a result, reduction in cost of the test fixture 28 to measure the electrical characteristics of various semiconductor devices 8 can be expected.

Embodiment 6 is applicable to Embodiments 1 to 5. For example, when Embodiment 6 is applied to Embodiment 2, the restrictor 17 prevents contact between the body 30 of the pogo pin block 4 and the second substrate 3 and forms the gap of several tens to several hundreds of micrometers between them, so that a similar effect to that obtained in Embodiment 2 can be obtained.

### Embodiment 7

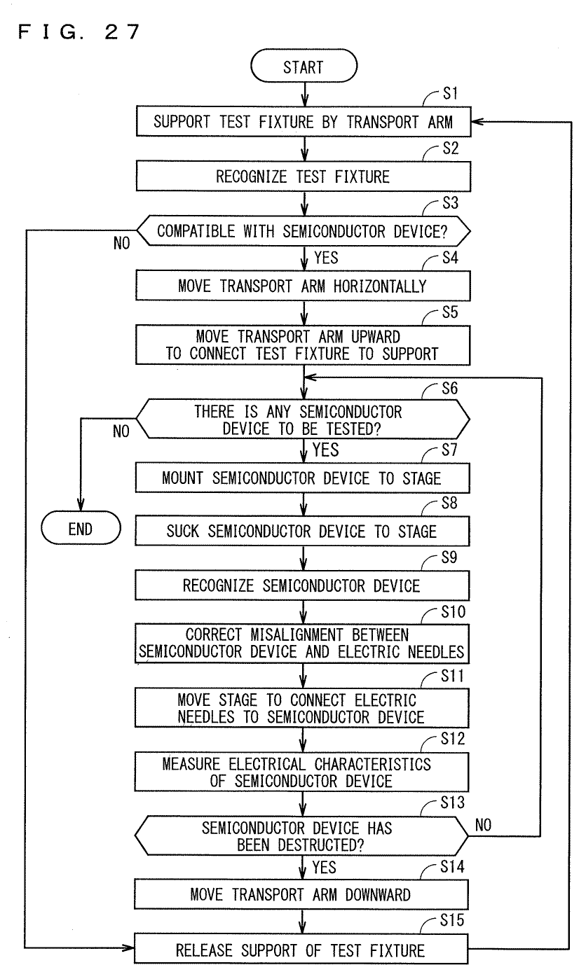

FIG. 27 is a flowchart showing a method of manufacturing a semiconductor device according to Embodiment 7. The manufacturing method is performed by each of the semiconductor manufacturing devices according to Embodiments 1 to 6.

In step S1, the transport arm 9 supports one of the plurality of test fixtures 28 that is suitable for measurement of the electrical characteristics of the semiconductor device 8. In this case, the pins 12 of the transport arm 9 position the one test fixture 28 relative to the transport arm 9. In step S2, the semiconductor manufacturing device reads an unillustrated two-dimensional barcode and the like of the test fixture 28 supported by the transport arm 9 to recognize the test fixture 28.

In step S3, the semiconductor manufacturing device determines whether the recognized test fixture 28 is compatible with the semiconductor device 8 to be tested. Processing proceeds to step S4 when it is determined that the recognized test fixture 28 is compatible and proceeds to step S15 when it is not determined that the recognized test fixture 28 is compatible.

In step S4, the transport arm 9 is moved horizontally (e.g., in the Y direction) to transport the recognized test fixture 28 to above the stage 10. In step S5, the transport arm 9 is moved upward (in the Z direction) to transport the test fixture 28 having been transported to above the stage 10 toward the support 16. Due to this transport, the test fixture 28 is connected to the support 16, and the electric needles 6 are electrically connected to the bottom surface conductive pattern 23 of the first substrate 2. In this case, the pins 12 of the test fixture 28 position the test fixture 28 relative to the support 16.

In step S6, the semiconductor manufacturing device determines whether there is any semiconductor device 8 to be tested. Processing proceeds to step S7 when it is determined that there is the semiconductor device 8 to be tested, and operation in FIG. 27 ends when it is not determined that there is the semiconductor device 8 to be tested.

In step S7, the semiconductor manufacturing device mounts the semiconductor device 8 to be tested to the stage 10. In step S8, the semiconductor manufacturing device sucks the mounted semiconductor device 8 to the stage 10. In step S9, the semiconductor manufacturing device recognizes the sucked semiconductor device 8 using an unillustrated camera. In step S10, the semiconductor manufacturing device controls the stage 10 based on misalignment between the recognized semiconductor device 8 and the electric needles 6 electrically connected to the bottom surface conductive pattern 23 to correct the misalignment.

In step S11, the stage 10 is moved toward the test fixture 28 to electrically connect the electric needles 6 to the semiconductor device 8 and to electrically connect the conductive member 5 to the conductive elastic member 7 of the stage 10. In step S12, the semiconductor manufacturing device measures the electrical characteristics of the semiconductor device 8 by the tester 1. In step S13, the semiconductor manufacturing device detects destruction or non-destruction of the semiconductor device 8 through measurement of the electrical characteristics based on a result of measurement, for example. Processing proceeds to step S14 when destruction of the semiconductor device 8 is detected and proceeds to step S6 and testing for measurement of the semiconductor device 8 is continued as appropriate when non-destruction of the semiconductor device 8 is detected.

In step S14, the transport arm 9 is moved downward to release electrical connection between the electric needles 6 and the bottom surface conductive pattern 23 of the first substrate 2 and is moved horizontally. In step S15, the transport arm 9 releases support of the test fixture 28 currently being supported. Processing then proceeds to step S1, and the transport arm 9 supports another one of the plurality of test fixtures 28 that is suitable for measurement of the electrical characteristics of the semiconductor device 8. That is to say, the test fixture 28 is automatically replaced when destruction of the semiconductor device 8 is detected.

According to the manufacturing method using the semiconductor manufacturing device according to Embodiment 7 as described above, the test fixture 28 is automatically replaced when destruction of the semiconductor device 8 is detected through measurement of the electrical characteristics of the semiconductor device 8. According to such a configuration, a downtime in testing for measurement of the electrical characteristics of the semiconductor device 8 can be reduced. Furthermore, a worker's effect to check a model of the test fixture 28 and set the test fixture 28 and the like can be saved when testing for measurement is conducted on various semiconductor devices 8 differing in arrangement of the electrode pads.

Indefinite articles ‘a’ and ‘an’ in the present disclosure in English mean one or more. Thus, ‘a’, ‘an’, ‘one or more’, and ‘at least one’ can be used interchangeably.

Embodiments and modifications can freely be combined with each other and can be modified or omitted as appropriate.

Various aspects of the present disclosure will collectively be described below as appendices.

### Appendix 1

A semiconductor manufacturing device comprising:
a stage to which a semiconductor device is mounted;
a support disposed above the stage and including a first substrate; and
a test fixture capable of being disposed between the stage and the support, wherein
the first substrate includes, in a top surface thereof, a top surface conductive pattern electrically connected to a bottom surface portion as a portion of a bottom surface of the first substrate,
the first substrate includes, in a portion of the bottom surface other than the bottom surface portion of the first substrate, a bottom surface conductive pattern disposed along the top surface conductive pattern,
the test fixture comprises:
   an electric needle electrically connectable to the semiconductor device;
   a second substrate disposed on a top side of the electric needle and including a bottom portion electrically connected to the electric needle and a top portion electrically connected to the bottom portion; and
   an insulating plate member covering a top portion of the electric needle on a bottom side of the second substrate and capable of electrically connecting the electric needle to the bottom portion of the second substrate,
the support or the test fixture comprises
   a pogo pin block including a pogo pin electrically connected to any one of the bottom surface conductive pattern of the first substrate and the top portion of the second substrate and movable toward and away from the other one of the bottom surface conductive pattern of the first substrate and the top portion of the second substrate,
the support or the test fixture comprises
   a conductive member capable of being disposed along the electric needle and capable of electrically connecting the stage to the bottom surface portion of the first substrate, and
the semiconductor manufacturing device further comprises:
   a tester electrically connected to the bottom surface conductive pattern and the top surface conductive pattern; and
   a transporter to transport the test fixture toward the support to electrically connect the electric needle to the bottom surface conductive pattern via the second substrate and the pogo pin block.

### Appendix 2

The semiconductor manufacturing device according to Appendix 1, wherein
the test fixture comprises the pogo pin block,
the pogo pin of the pogo pin block is electrically connected to the top portion of the second substrate regardless of whether the test fixture is transported toward the support, and
the test fixture is transported toward the support to electrically connect the pogo pin of the pogo pin block to the bottom surface conductive pattern of the first substrate.

### Appendix 3

The semiconductor manufacturing device according to Appendix 1 or 2, wherein
the test fixture comprises the conductive member,
the conductive member is disposed along the electric needle regardless of whether the test fixture is transported toward the support, and
the test fixture is transported toward the support to electrically connect the conductive member to the bottom surface portion of the first substrate.

### Appendix 4

The semiconductor manufacturing device according to Appendix 1, wherein
the support comprises the pogo pin block,
the pogo pin of the pogo pin block is electrically connected to the bottom surface conductive pattern of the first substrate regardless of whether the test fixture is transported toward the support, and
the test fixture is transported toward the support to electrically connect the pogo pin of the pogo pin block to the top portion of the second substrate.

### Appendix 5

The semiconductor manufacturing device according to Appendix 4, wherein
the support comprises
   an insulating restrictor to prevent contact between a body of the pogo pin block and the second substrate when the electric needle is electrically connected to the bottom surface conductive pattern.

### Appendix 6

The semiconductor manufacturing device according to any one of Appendices 1 to 5, wherein
the conductive member of the support or the test fixture comprises a plurality of conductive members.

### Appendix 7

The semiconductor manufacturing device according to any one of Appendices 1 to 6, wherein
the conductive member surrounds a plurality of electric needles electrically connected to the semiconductor device in plan view.

### Appendix 8

The semiconductor manufacturing device according to Appendix 1 or 4, wherein
the support comprises the conductive member,
the conductive member is electrically connected to the bottom surface portion of the first substrate regardless of whether the test fixture is transported toward the support, and
the test fixture is transported toward the support to dispose the conductive member along the electric needle.

### Appendix 9

The semiconductor manufacturing device according to any one of Appendices 1 to 8, wherein
the second substrate comprises:
   a bottom conductive pattern as the bottom portion of the second substrate;
   a top conductive pattern as the top portion of the second substrate; and
   a conductor disposed in a through hole vertically extending through the second substrate, the conductor electrically connecting the bottom conductive pattern to the top conductive pattern.

### Appendix 10

The semiconductor manufacturing device according to Appendix 9, wherein
the bottom surface portion is a first bottom surface portion,
the first substrate includes, in the top surface thereof, a small signal pattern electrically connected to a second bottom surface portion as a portion of the bottom surface of the first substrate different from the first bottom surface portion, and
the through hole of the second substrate is located to face the bottom surface conductive pattern and the second bottom surface portion.

### Appendix 11

The semiconductor manufacturing device according to any one of Appendices 1 to 8, wherein
the second substrate comprises a conductor electrically connectable to the bottom surface conductive pattern.

### Appendix 12

The semiconductor manufacturing device according to any one of Appendices 1 to 8, wherein
the insulating plate member comprises
   a protrusion protruding from a top surface of the insulating plate member and electrically connected to the electric needle, and
the second substrate comprises:
   a conductive wire;
   a terminal block as a top surface of the second substrate; and
   a terminal disposed in the terminal block and electrically connected to the protrusion by the conductive wire.

### Appendix 13

A method of manufacturing a semiconductor device using the semiconductor manufacturing device according to any one of Appendices 1 to 12, the method comprising:
supporting the test fixture by the transporter;
recognizing the test fixture supported by the transporter;
transporting the recognized test fixture to above the stage by the transporter;
transporting, by the transporter, the test fixture having been transported to above the stage toward the support to electrically connect the electric needle to the bottom surface conductive pattern;
mounting the semiconductor device to the stage;
sucking the mounted semiconductor device to the stage;
recognizing the sucked semiconductor device;
correcting misalignment between the recognized semiconductor device and the electric needle electrically connected to the bottom surface conductive pattern;
after correcting the misalignment, moving the stage toward the test fixture to electrically connect the electric needle to the semiconductor device and to electrically connect the conductive member to the stage;
measuring electrical characteristics of the semiconductor device by the tester;
detecting destruction or non-destruction of the semiconductor device through measurement of the electrical characteristics; and
automatically replacing the test fixture when destruction of the semiconductor device is detected.

While the disclosure has been shown and described in detail, the foregoing description is in all aspects illustrative and not restrictive. It is therefore understood that numerous modifications and variations can be devised without departing from the scope of the disclosure.

What is claimed is:

1. A semiconductor manufacturing device comprising:
a stage to which a semiconductor device is mounted;
a support disposed above the stage and including a first substrate; and
a test fixture capable of being disposed between the stage and the support, wherein
the first substrate includes, in a top surface thereof, a top surface conductive pattern electrically connected to a bottom surface portion as a portion of a bottom surface of the first substrate,
the first substrate includes, in a portion of the bottom surface other than the bottom surface portion of the first substrate, a bottom surface conductive pattern disposed along the top surface conductive pattern,
the test fixture comprises:
an electric needle electrically connectable to the semiconductor device;
a second substrate disposed on a top side of the electric needle and including a bottom portion electrically connected to the electric needle and a top portion electrically connected to the bottom portion; and
an insulating plate member covering a top portion of the electric needle on a bottom side of the second substrate and capable of electrically connecting the electric needle to the bottom portion of the second substrate,
the support or the test fixture comprises
a pogo pin block including a pogo pin electrically connected to any one of the bottom surface conductive pattern of the first substrate and the top portion of the second substrate and movable toward and away from the other one of the bottom surface conductive pattern of the first substrate and the top portion of the second substrate,
the support or the test fixture comprises
a conductive member capable of being disposed along the electric needle and capable of electrically connecting the stage to the bottom surface portion of the first substrate, and
the semiconductor manufacturing device further comprises:
a tester electrically connected to the bottom surface conductive pattern and the top surface conductive pattern; and
a transporter to transport the test fixture toward the support to electrically connect the electric needle to the bottom surface conductive pattern via the second substrate and the pogo pin block.

2. The semiconductor manufacturing device according to claim 1, wherein
the test fixture comprises the pogo pin block,
the pogo pin of the pogo pin block is electrically connected to the top portion of the second substrate regardless of whether the test fixture is transported toward the support, and
the test fixture is transported toward the support to electrically connect the pogo pin of the pogo pin block to the bottom surface conductive pattern of the first substrate.

3. The semiconductor manufacturing device according to claim 1, wherein
the test fixture comprises the conductive member,
the conductive member is disposed along the electric needle regardless of whether the test fixture is transported toward the support, and
the test fixture is transported toward the support to electrically connect the conductive member to the bottom surface portion of the first substrate.

4. The semiconductor manufacturing device according to claim 1, wherein
the support comprises the pogo pin block,
the pogo pin of the pogo pin block is electrically connected to the bottom surface conductive pattern of the first substrate regardless of whether the test fixture is transported toward the support, and
the test fixture is transported toward the support to electrically connect the pogo pin of the pogo pin block to the top portion of the second substrate.

5. The semiconductor manufacturing device according to claim 4, wherein
the support comprises
an insulating restrictor to prevent contact between a body of the pogo pin block and the second substrate when the electric needle is electrically connected to the bottom surface conductive pattern.

6. The semiconductor manufacturing device according to claim 1, wherein
the conductive member of the support or the test fixture comprises a plurality of conductive members.

7. The semiconductor manufacturing device according to claim 1, wherein
the conductive member surrounds a plurality of electric needles electrically connected to the semiconductor device in plan view.

8. The semiconductor manufacturing device according to claim 1, wherein
the support comprises the conductive member,
the conductive member is electrically connected to the bottom surface portion of the first substrate regardless of whether the test fixture is transported toward the support, and
the test fixture is transported toward the support to dispose the conductive member along the electric needle.

9. The semiconductor manufacturing device according to claim 1, wherein
the second substrate comprises:
a bottom conductive pattern as the bottom portion of the second substrate;
a top conductive pattern as the top portion of the second substrate; and
a conductor disposed in a through hole vertically extending through the second substrate, the conductor electrically connecting the bottom conductive pattern to the top conductive pattern.

10. The semiconductor manufacturing device according to claim 9, wherein
the bottom surface portion is a first bottom surface portion,
the first substrate includes, in the top surface thereof, a small signal pattern electrically connected to a second bottom surface portion as a portion of the bottom surface of the first substrate different from the first bottom surface portion, and
the through hole of the second substrate is located to face the bottom surface conductive pattern and the second bottom surface portion.

11. The semiconductor manufacturing device according to claim 1, wherein
the second substrate comprises a conductor electrically connectable to the bottom surface conductive pattern.

12. The semiconductor manufacturing device according to claim 1, wherein
the insulating plate member comprises
a protrusion protruding from a top surface of the insulating plate member and electrically connected to the electric needle, and
the second substrate comprises:
a conductive wire;
a terminal block as a top surface of the second substrate; and
a terminal disposed in the terminal block and electrically connected to the protrusion by the conductive wire.

13. A method of manufacturing a semiconductor device using the semiconductor manufacturing device according to claim 1, the method comprising:
supporting the test fixture by the transporter;
recognizing the test fixture supported by the transporter;
transporting the recognized test fixture to above the stage by the transporter;
transporting, by the transporter, the test fixture having been transported to above the stage toward the support to electrically connect the electric needle to the bottom surface conductive pattern;
mounting the semiconductor device to the stage;
sucking the mounted semiconductor device to the stage;
recognizing the sucked semiconductor device;
correcting misalignment between the recognized semiconductor device and the electric needle electrically connected to the bottom surface conductive pattern;
after correcting the misalignment, moving the stage toward the test fixture to electrically connect the electric needle to the semiconductor device and to electrically connect the conductive member to the stage;
measuring electrical characteristics of the semiconductor device by the tester;
detecting destruction or non-destruction of the semiconductor device through measurement of the electrical characteristics; and
automatically replacing the test fixture when destruction of the semiconductor device is detected.
